(19) United States
(12) Patent Application Publication
(10) Pub. No.: US 2006/0057763 A1
(43) Pub. Date: Mar. 16, 2006

(54) Method of forming a surface mountable IC and its assembly

(75) Inventors: Poi Siong Teo, Singapore (SG); Ser Choong Chong, Singapore (SG); Sampath Srinivasamurthy, Singapore (SG)

Correspondence Address: STEPHEN B. ACKERMAN, 28 DAVIS AVENUE, POUGHKEEPSIE, NY, 12603, US

(73) Assignee: Agency For Science, Technology And Research

(21) Appl. No.: 10/940,436

(22) Filed: Sep. 14, 2004

(51) Int. Cl. H01L 21/44

(52) U.S. Cl. 438/64; 438/119

(57) ABSTRACT

A flip-chip interconnect structure for a RFID tag is described which permits the use of an isotropic electrically conductive adhesive (ECA) without requirement of critical alignment of the chip terminal pads to antenna terminals on the substrate. The interconnect foot print utilizes design principles of standard discrete SMD terminal footprint, which does not require alignment accuracy of a NCA/ACA flip chip bonder. The use of an ECA also eliminates the need for curing the adhesive while under heat and pressure on the chip placement machine. Because of the wide placement tolerance the chips can be placed with a low cost highly productive SMT placement machine. After placement, the assemblies leave the placement machine and are cured in an oven, thereby further improving the productivity of the placement machine. Further productivity improvement is realized by the elimination of bumping which is no longer required. The overall cost reduction of the final assembly by the process of the invention is estimated at about 60 to 85 percent.

### BACKGROUND OF THE INVENTION

(1) Field of the Invention

The invention relates to processes for the manufacture of integrated circuits and more particularly to the mounting of an integrated circuit chip onto a substrate by a surface mount method

(2) Background of the Invention and Description of Previous Art

Flip chip microelectronic assembly is the direct electrical connection of face-down electronic components or integrated circuit chips onto substrates, circuit boards, or carriers by means of conductive bumps on the chip bond pads. In contrast, wire bonding, the older technology which flip chip replaces, uses face-up chips with a wire connection to each pad. Flip chip components are predominantly semiconductor devices; however, components such as passive filters, detector arrays, and MEMs devices are also beginning to be used in flip chip form. Flip chip is also called Direct Chip Attach (DCA), a more descriptive term, since the chip is directly attached to the substrate, board, or carrier by the conductive bumps. IBM introduced flip chip interconnection in the early sixties for their mainframe computers, and has continued to use flip chip since then. Delco Electronics developed flip chips for automotive applications in the seventies. Delphi Delco currently places over 300,000 flip chip die per day into automotive electronics. Most electronic watches, and a growing percentage of cellular phones, pagers, and high speed microprocessors are assembled with flip chip.

One application of flip-chip technology is the manufacture of RFID (radio Frequency Identification) tags. These miniature rf transponders, also known as “smart labels” are embedded or otherwise attached on various articles to provide remote identification and location information, for example, for automobiles, credit cards, store merchandise, migratory birds, proximity detecting devices, and other objects which may need to be traced or identified. RFID tags are manufactured as flip-chip assemblies wherein the rf antenna is formed on a substrate, to which a tiny memory and processor integrated circuit chip is bonded. The memory/processor chip can connect with a host application through RF (Radio Frequency) communication. The RFID smart labels have a limited memory capacity (in the range of 32-256 bytes) that can be read or written to multiple times by means of a reader that connects to a computer. The labels do not need a separate power supply. They operate on transmitted rf radiation that is picked up by the antenna. The size of the labels is determined by size of the antenna and is approximately 3×3 cm (1.5×1.5 inch). A disadvantage of this is that the labels cannot be used on metal objects.

Currently, the RFID chips are bonded to the antenna bearing substrate with either a non-conducting adhesive (NCA) or an anisotropic-conductive adhesive (ACA). In either case, electrical connection is achieved through metal bumps on the IC chip which penetrate the adhesive and make direct contact to the rf antenna. Brady, et. al., U.S. Pat. No. 6,259,408 B1, attaches an RFID chip to an antenna which is printed on a substrate which may be a rigid material such as ceramic but can also be a flexible material such as a thin polyimide or polyester film. The antenna is formed of a polymer resin containing silver particles. Bonding of the metallic chip bumps to the antenna is accomplished by applying heat and downward pressure to the chip for a period of time.

FIG. 1 illustrates the formation of a prior art RFID assembly. In FIG. 1c, a substrate 6 is provided having an antenna 8 patterned on it. The antenna 8 may consist of a dipole or a coil pattern and have terminal pads 10. In FIG. 1f a layer of an adhesive 16 such as an ACA or an NCA is patterned, by a silk screening process or dispensing process onto the antenna terminal pads 10.

An integrated circuit chip 12, shown in planar view in FIG. 1a and in cross section in FIG. 1b, is to be mounted and connected to the antenna terminal pads using the flip-chip method. The IC chip 12 has corresponding terminal pads 14 patterned in an upper conductive layer and exposed in openings in an insulating passivation layer 16, at the end of the chip personalization processing. In FIGS. 1d and 1e conductive posts (bumps) 18, typically consisting of a metal such as gold or Ni, are patterned onto the chip terminal pads 12. Kreibel, F., and Seidowski., T., “Smart labels-high volume applications using adhesive flip-chip-technologies”, Proceedings of First International IEEE Conference on Polymers and Adhesives in Microelectronics and Photonics, 21-24 Oct. 2001, pages 304-308 teaches the use of electroless deposited Pd—Ni bumps in combination with an ACA or NCA. Isotropic electrically conducting adhesives (ICAs) are not recommended because they must be applied locally and also require long curing times.

The chip 12 is now flipped over and the bumps 18 aligned to the antenna terminal pads 10 through the adhesive 16. Referring to FIG. 1g, pressure must now be applied to force the bumps into contact with the antenna pads 10. Heat is applied to cure the adhesive 16′ leading to the final product shown in FIG. 1h. In the final product, if an ACA is used, the bulk of the adhesive is cured but remains insulative while the portion which is entrapped between the bumps 18 and the antenna pads 10 becomes conductive.

Seidowski, et. al., German Patent Number DE-19905807 A1, teaches the roughening of the bump surface in the form of wedges, cones, or pyramids. These features penetrate any native film, such as a native oxide formed on an aluminum pattern, thus assuring a good ohmic contact when the bump is pressed onto the substrate.

The main disadvantage of the existing RFID tag assembly using the flip-chip process is still high manufacturing cost. This is driven mainly by low productivity, arising from the slow IC alignment and bonding process which involves the application of heat for an extended period under bonding pressure. A further problem with the use of ACA is that the interconnect pressure bonding and adhesive curing must be done on the placement machine which creates a serious production bottleneck. The high manufacturing cost and low productivity is still the main obstacle that prevents widespread adoption of the RFID tag. A variety of approaches have been proposed by other researchers to reduce the manufacturing cost. These approaches concentrate on reducing the cure time of the bonding adhesive and the use of cheaper substrate materials.

It is therefore desirable to have a method for forming a RFID smart tag assembly which will overcome the productivity problems created primarily by the need for bonding pressure when an ACA is used. The present invention improves the productivity of RFID tag assembly by a novel combination of physical IC structural (design) changes which permits the use of an ECA without the need for critical time consuming alignment of the chip with the substrate antenna terminal pads. Consequently the adhesive can be cured after removal of the assembly from the chip placement machine, thereby eliminating the processing bottleneck at this station.

The simplest footprint for mounting and interconnecting a standard SMD (surface mounted Device) embodies a chip 132 with a two terminal pad footprint which is illustrated in planar and cross-sectional view in FIGS. 2a and 2b respectively. This is the footprint for the standard SMD. The SMD chip has a length “L” which is twice the width “W” Typically, the SMD is measured in mils. (1 mil.=0.001 inches). A 0603 footprint, for example, indicates that the SMD is 60 mils. long and 30 mils. wide. A 0402 SMD footprint is one where L=40 mils. and W=20 mils. The terminal pads 134 are much larger than those on alignment bonded chips like that shown in FIGS. 1a and 1b. The two-terminal standard discrete SMD chip, because of its large size does not require “bumping”—a significant productivity advantage.

### SUMMARY OF THE INVENTION

It is an object of this invention to provide a design of an interconnect structure for a RFID tag which permits the use of an ECA without requirement of critical alignment of the chip terminal pads or bumps to antenna terminals on the substrate.

It is another object of this invention to provide a design and assembly process of an interconnect structure for a RFID tag which significant improves productivity and lowers production cost.

It is yet another object of this invention to describe a design and assembly process of an interconnect structure for a RFID tag whereby terminal pads on the chip are connected directly to corresponding terminal pads on the substrate eliminates the need for forming bumps on the chip terminals.

It is yet another object of this invention to describe a design and assembly process of an interconnect structure for a RFID tag which eliminates the need for pressure application during adhesive curing.

It is yet another object of this invention to describe a design and assembly process of an interconnect structure for a RFID tag wherein the curing of the bonding adhesive is performed in a separate process step after removal of the assembly from the chip placement machine.

These objects are accomplished by designing the RFID chip terminal pads and the corresponding antenna terminal pads on the substrate in a way that the footprint of the connection complies with the footprint of standard discrete SMD. This provides a relatively large interconnect pad area which provides a wide alignment tolerance. The key benefit of designing and fabricating the RFID chip into the form of the standard discrete SMD footprint is that placement of the chip onto the substrate can be carried out with an SMT (Surface Mount Technology) placement machine which is well known in the assembly of printed circuit boards, and is capable of much greater productivity than conventional, critical alignment, flip chip bonding tools.

### BRIEF DESCRIPTION OF THE DRAWINGS

FIGS. 1a through 1h are members of a flow diagram showing cross sections of the preparation and the mounting process of a RFID tag chip and its antenna bearing substrate according to a prior art procedure.

FIGS. 2a and 2b are planar and cross sectional views respectively of a prior art standard discrete SMD chip.

FIG. 3a through 3f are members of a flow diagram showing cross sections of the preparation and the mounting process of a RFID tag chip and its antenna bearing substrate according to the procedure taught by the present invention.

FIGS. 4a and 4b are a planar and cross sectional views respectively of a three terminal variation of the integrated circuit chip having a standard discrete SMD terminal footprint, as applied in the present invention.

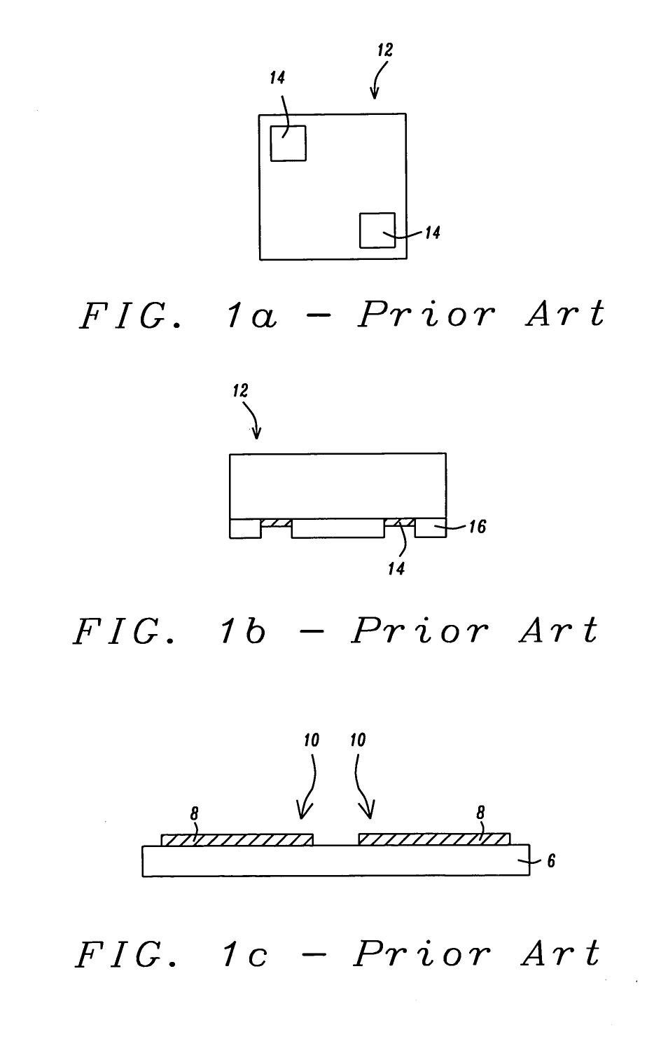

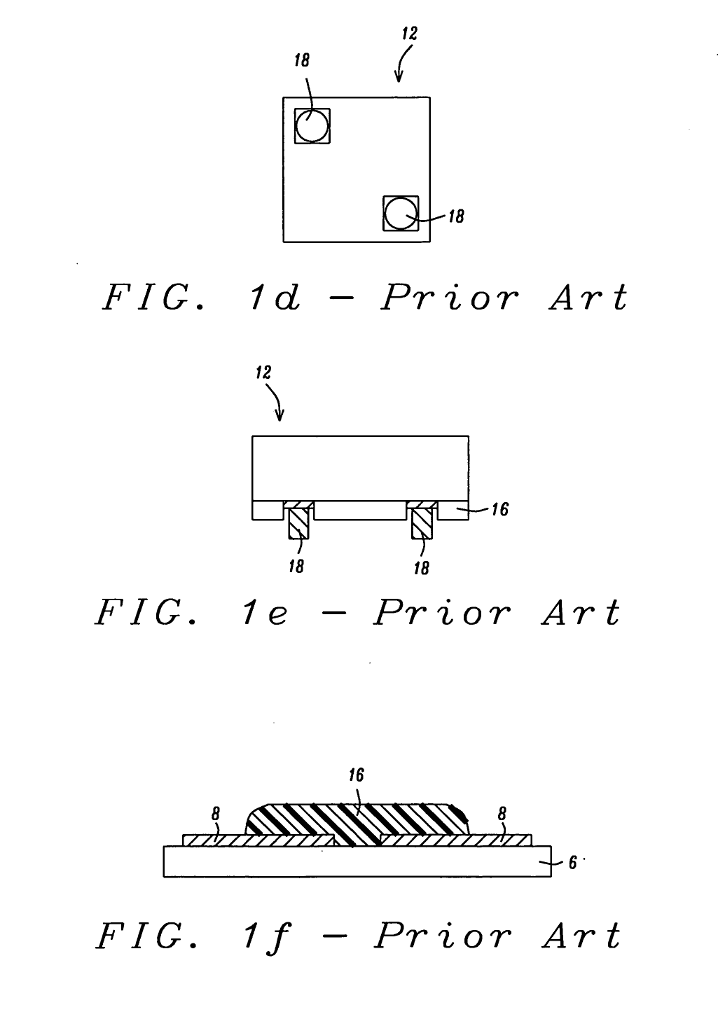

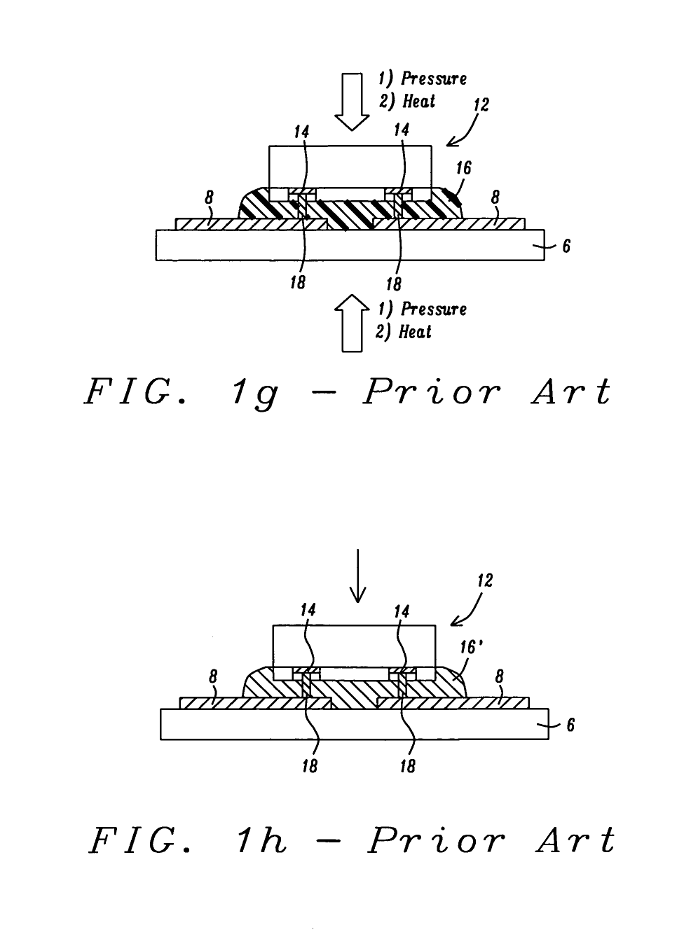

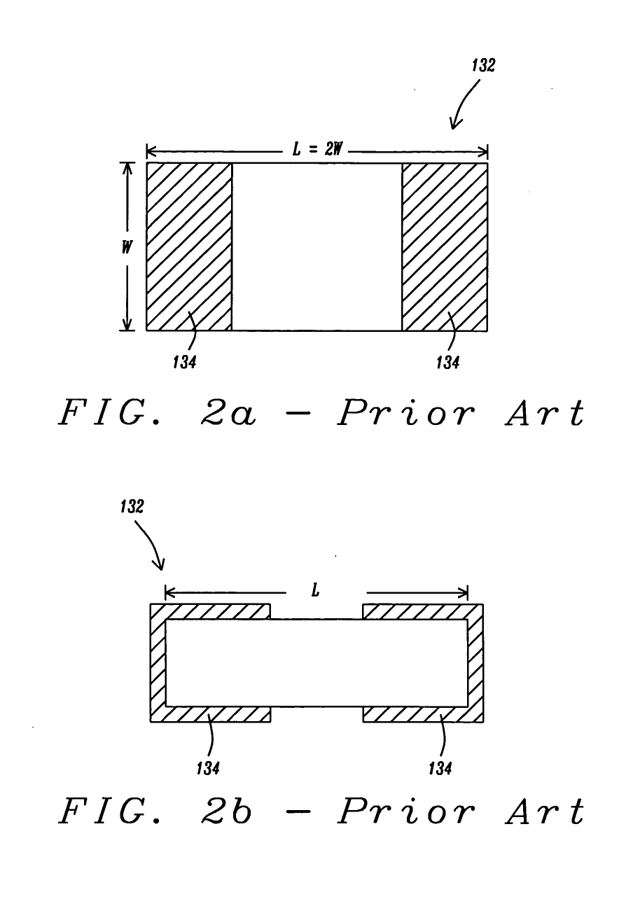

### DESCRIPTION OF THE PREFERRED EMBODIMENTS

In a first embodiment of this invention a novel assembly process for mounting an RFID tag on an antenna bearing substrate is described. A key feature of the process is the use of a chip of discrete SMD terminal footprint to mount and interconnect the chip to the substrate, using an isotropic electrically conductive adhesive.

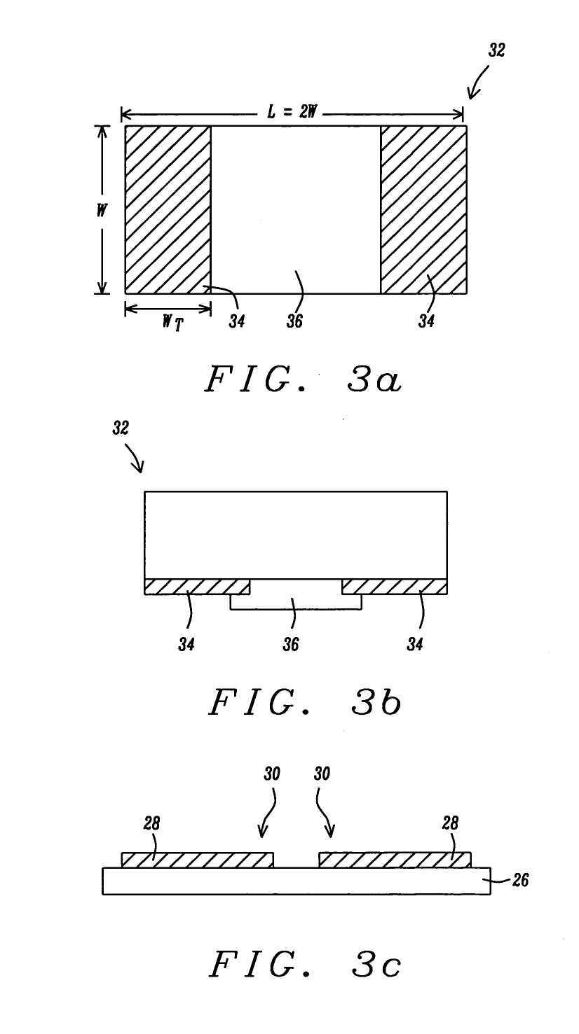

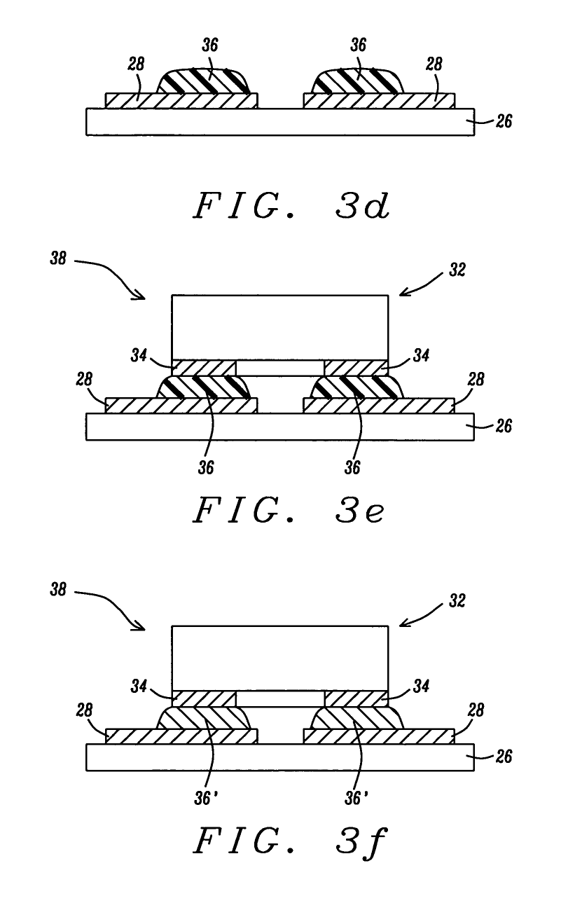

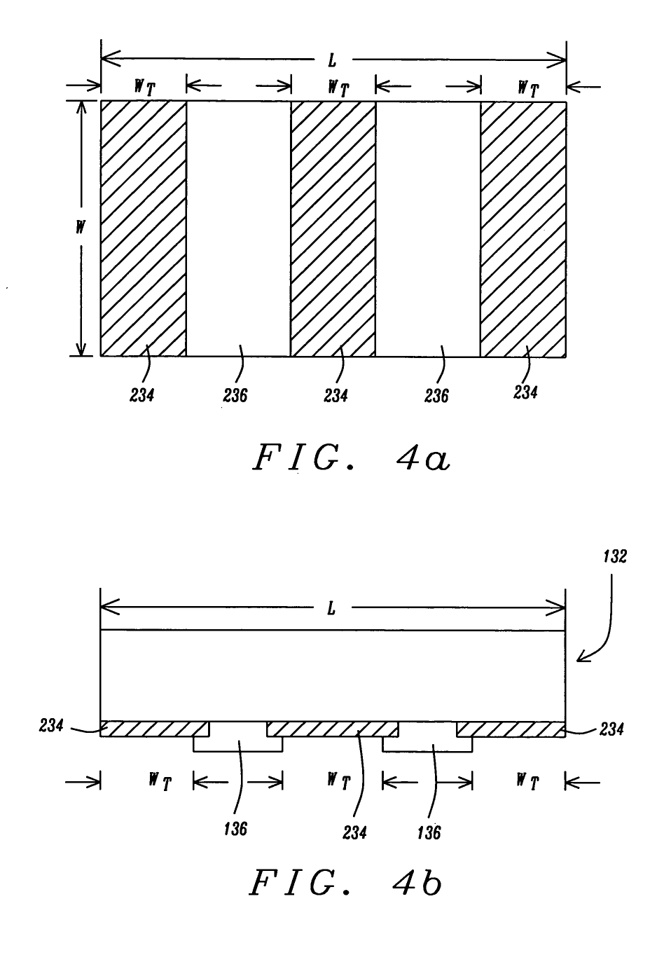

Referring now to FIGS. 3a, 3b and 3c, a RFID tag integrated circuit chip 32 having a standard discrete SMD terminal footprint is shown. RFID chip 32 is to be mounted and interconnected to an rf antenna 28 which has been patterned on substrate 26. The RF antenna is formed by patterning and curing a conductive paste on the substrate 26. Alternately the RF antenna 28 may be formed by patterning a metal sheet which has been bonded onto the carrier substrate 26. Rf Antenna 28 may be either of coil, dipole, or other two terminal configuration having terminals 30 at locations which, in accordance with standard discrete SMD guidelines are patterned to match the footprint on the RFID tag chip 32.

In this embodiment the RFID integrated circuit chip has a width “W” between about 18 and 22 mils. and a length “L” between about 38 and 42 mils. which corresponds to a 0402 SMD footprint. The width “W_{T}” of the antenna interconnect terminal pads 34 is between about 9.8 and 10.2 mils. and have a length of “W”.

The substrate 26 is next picked and sent to an in-line adhesive delivery tool which dispenses or prints an isotropic electrically conductive adhesive (ECA) 36 onto the antenna terminals 30 (FIG. 3d). The substrate 26 and the RFID tag chip 32 are then loaded into a SMT chip placement machine, for example, the Model CM402 manufactured by Panasonic Factory Solutions Co., Ltd., 2-7, Matsuba-cho, Kadoma, Osaka, Japan. This placement machine is capable of a placement rate of 60,000 components per hour. This is to be compared to a placement rate of 2,000 components per hour for a high throughput NCA/ACA Flip-chip bonder such as the model FCB3 manufactured by Panasonic Factory Solutions Co., Ltd., 2-7, Matsuba-cho, Kadoma, Osaka, Japan. It is also to be noted that the quoted placement rate of 2,000 components per hour does not include the time needed to apply heat to cure the NCA/ACA adhesive which is a variable from 5-30 seconds depending on the material used. When this is factored in, the NCA/ACA bonder placement rate is reduced to about 530 components per hour at best. In the SMT placement machine the RFID chip 32 is placed onto the substrate whereupon the terminals 34 become interconnected with the antenna terminals 30 through the adhesive 36 and form the RFID tag assembly 38 shown in FIG. 3e. After placement, the assembly 38 leaves the placement machine and enters a curing oven wherein the adhesive 36′ is cured (FIG. 3f) to complete the process. The curing process is accomplished without applied pressure and is conducted in an air or inert gas ambient at a temperature of between about 100 and 175° C. in an ambient of air or inert gas for a period of between about 15 and 60 minutes. Preferably, the curing process is performed as a continuous flow process wherein RFID tag assemblies pass through the curing oven on a conveyor belt. Alternately, the assemblies may be accumulated from the placement machine onto a tray or the like and then cured in a batch oven. Alternately, adhesives curable by other curing mechanisms may be used. These include, but are not limited to, microwave and room temperature curable adhesives.

While the embodiments of this invention utilizes a two terminal standard discrete SMD footprint design to form a RFID tag chip assembly, it should be understood that variations in the footprint length to width ratio as well as extension to more than two terminals. Such a footprint is show in planar an cross section in FIGS. 4a and 4b respectively. Further, it should be understood that the standard L=2 W relationship need not be strictly adhered to but may be replaced by other relationships between L and W. Further, an empirically determined relationship between W and the terminal width WT may be developed, depending on the interconnect yield.

While this invention has been particularly shown and described with reference to the preferred embodiments thereof, it will be understood by those skilled in the art that various changes in form and details may be made without departing from the spirit and scope of the invention.

What is claimed is:

1. A method for forming a surface mountable integrated circuit and its assembly onto a carrier substrate comprising:
(a) providing a rectangular semiconductor chip having
(i) a chip upper surface;
(ii) an integrated circuit formed within said chip upper surface; and
(ii) conductive wiring in said chip upper surface terminating in at least two conductive terminal pads exposed through openings in a passivation layer on said chip upper surface wherein two of said at least two conductive chip terminal pads are formed on opposite sides of said chip upper surface, each pad having a width and a length, said length extending on said chip upper surface and along an entire side of said chip thereby forming a chip footprint;
(b) providing a carrier substrate having a conductive layer patterned on its upper surface, said conductive layer having at least two terminal tabs arranged in a carrier footprint which is a mating footprint of said chip footprint;
(c) selectively applying an isotropic electrically conductive adhesive to each one of said at least two terminal tabs on said carrier substrate;
(d) loading said carrier substrate and said semiconductor chip into an a placement machine;
(e) causing said placement machine to place said semiconductor chip onto said carrier substrate, whereby said at least two conductive terminal pads engage and are lightly pressed into said conductive adhesive on corresponding said terminal tabs on said carrier substrate, there by forming an assembly;
(f) transferring said assembly from said placement machine into a curing chamber; and
g) curing said isotropic electrically conductive adhesive.

2. The method of claim 1 wherein said chip terminal footprint is a standard SMD terminal footprint.

3. The method of claim 1 wherein said placement machine is an SMT placement machine.

4. A method for forming a RFID tag assembly comprising:
(a) providing a rectangular semiconductor chip having
(i) a chip upper surface;
(ii) an RFID integrated circuit formed within said chip upper surface; and
(iii) conductive wiring in said chip upper surface terminating in two conductive antenna interconnect chip terminal pads, exposed through openings in a passivation layer on said chip upper surface and wherein said two chip terminal pads are formed, each one on the opposite side of the other, and each chip terminal pad having a width and a length, said length extending along the entire side of said chip, both pads thereby forming a chip terminal pad footprint;
(b) providing a carrier substrate having a conductive layer patterned on its upper surface to form a rf antenna, said rf antenna having two terminal tabs arranged in a footprint on said carrier substrate which is a mating footprint of said chip terminal pad footprint;
(c) selectively applying an isotropic electrically conductive adhesive to each one of said two terminal tabs on said carrier substrate;
(d) loading said carrier substrate and said semiconductor chip into a placement machine.
(e) causing said placement machine to place said semiconductor chip onto said carrier substrate, whereby said two conductive chip terminal pads engage and are lightly pressed into said conductive adhesive on corresponding terminal tabs on said carrier substrate, there by forming a RFID tag assembly;
(f) transferring said RFID tag assembly from said placement machine into a curing chamber; and
(g) curing said isotropic electrically conductive adhesive.

5. The method of claim 4 wherein said antenna is formed by depositing patterning, and curing a conductive paste on said carrier substrate.

6. The method of claim 5 wherein said antenna is a dipolar antenna or a coil antenna.

7. The method of claim 4 wherein said antenna is formed by patterning a metal sheet bonded onto said carrier substrate.

8. The method of claim 7 wherein said antenna is a dipolar antenna or a coil antenna.

9. The method of claim 4 wherein said isotropic electrical conducting adhesive consists of a polymeric adhesive filled with conductive fillers

10. The method of claim 9 wherein said isotropic electrical conducting adhesive is a thermal curing adhesive and is cured in said curing chamber at between about 100 and 175° C. in an ambient of air or inert gas for a period of between about 15 and 60 minutes.

11. The method of claim 9 wherein said isotropic electrical conducting adhesive is a room temperature curing adhesive or a microwave curing adhesive.

12. The method of claim 4 wherein said RFID integrated circuit chip is between about 18 and 22 mils. wide and between about 38 and 42 mils. long.

13. The method of claim 12 wherein said antenna interconnect terminal pads are between about 9.8 and 10.2 mils. long and with same width as chip.

14. The method of claim 4 wherein said chip terminal footprint is a standard SMD terminal footprint.

15. The method of claim 4 wherein said placement machine is an SMT placement machine.
